(19) United States
(12) Patent Application Publication
(10) Pub. No.: US 2008/0266150 A1
(43) Pub. Date: Oct. 30, 2008

(54) SERIAL DATA COMMUNICATION UNIT AND MEASURING DEVICE USING THE SAME

(75) Inventor: Satoru SUZUKI, Musashino-shi (JP)

Correspondence Address: SUGHRUE-265550, 2100 PENNSYLVANIA AVE. NW, WASHINGTON, DC, 20037-3213, US

(73) Assignee: YOKOGAWA ELECTRIC CORPORATION, Musashino-shi (JP)

(21) Appl. No.: 12/109,396

(22) Filed: Apr. 25, 2008

(30) Foreign Application Priority Data
Apr. 27, 2007 (JP) 2007-118471

(51) Int. Cl. H03M 9/00

(52) U.S. Cl. 341/100; 341/101

(57) ABSTRACT

A serial data communication unit includes a parallel-serial converter for separating n-bit parallel data containing decision data into plural groups, and converting the parallel data into serial data every group to output, a serial-parallel converter for reconverting the serial data fed from the parallel-serial converter every group into the n-bit parallel data to output, and a deciding circuit into which data located in bit positions corresponding to the decision data out of the parallel data from the serial-parallel converter is input.

This application claims priority to Japanese Patent Application No. 2007-118471, filed Apr. 27, 2007, in the Japanese Patent Office. The Japanese Patent Application No. 2007-118471 is incorporated by reference in its entirety.

### TECHNICAL FIELD

The present disclosure relates to a serial data communication unit for converting parallel data at a binary level (a high or low level) into serial data and making a data transmission and then reconverting the serial data that are transmitted into the original parallel data and outputting the data and a measuring device using this serial data communication unit. More particularly, the present disclosure relates to a serial data communication unit for detecting a lack of synchronism caused during data transmission of serial data without fail and a measuring device (a waveform measuring device, a wattmeter, or the like) using the same.

### RELATED ART

When the data communication is held, the number of signal lines is increased if the parallel data are transmitted as they are, and thus a difference in an amount of transmission delay between the parallel data, etc. are caused. For this reason, in most cases the communication is established after the parallel data are converted into serial data. In particular, in the case of the measuring device such as a waveform measuring device, a wattmeter, or the like, a communication using the serial data is held between the circuits for the purpose of an insulating process, a size reduction, and the like.

The serial data communication needs a timing clock to extract the data of each bit. Also, the serial data communication converts the parallel data into the serial data, so that a transmission rate higher than that of the parallel data is required of the serial data communication.

However, in case the data and the clock are transmitted through separate signal lines, it is difficult to synchronize the data and the clock on the receiver side. Therefore, the communication is held by using such a system that the clock is superposed on the serial data and then the serial data are transmitted, for example, by coding the serial data in terms of the “8b/10b conversion” (also called the “10b/8b conversion”) (see Patent Literature 1, for example).

[Patent Literature 1] Japanese Patent Application Publication No. 2003-318865

In the serial communication using the 8b/10b conversion, a parallel-serial converter (referred to as a “PS converter” hereinafter) on the transmitter side adds a redundancy bit to the 8-bit parallel data to get 10-bit parallel data, then converts this 10-bit parallel data into the serial data while superposing a clock signal on this data, and then outputs resultant serial data. In contrast, a serial-parallel converter (referred to as an “SP converter” hereinafter) on the receiver side reproduces the clock signal from the received serial data, then converts the serial data into the parallel data at a timing based on this clock signal, then reconverts this parallel data into the 8-bit parallel data by removing the redundancy bits from the 10-bit parallel data, and then outputs resultant parallel data.

Meanwhile, recently a bit width of the parallel bus is set larger than 8 bits, and the PS converter of the 8b/10b system put on the market has the input/output terminals of (8×k) bits. Also, the SP converter has a large number of input/output terminals so as to correspond to the PS converter.

In such PS converter, for example, when the 12-bit parallel data are transmitted from one PS converter, this PS converter separates 12 bits into a group of 8 upper bits and a group of 8 lower bits respectively (remaining 4 bits of the input/output terminals are connected to the ground and fixed at an “L” level), then converts grouped data into the serial data respectively, and then transmits a group of serial data on the upper bit side and then transmits a group of serial data on the lower bit side.

Also, the SP converter on the receiver side reconverts a group of data of the upper bit and a group of data of the lower bit into the parallel data respectively, then synchronizes the upper bits and the lower bits, and then outputs the resultant data onto a parallel bus as the 12-bit parallel data.

Therefore, in case the parallel data are transmitted in many times, the PS converter converts the upper bits and the lower bits of the parallel data into the serial data group sequentially, i.e., in order of the 1-st upper bit→the 1-st lower bit→the 2-nd upper bit→the 2-nd lower bit→the 3-rd upper bit . . . , respectively and then transmits the serial data groups sequentially to the SP converter.

In this manner, in case the parallel data has 9-bits or more, the SP converter on the receiver side must detect which serial data group out of the incoming serial data groups corresponds to the i-th head (i.e., the data group on the upper bit side).

Out of the PS converter and the SP converter that are put on the market now, the PS converter embeds a particular pattern on the head data by means of the 8b/10b conversion, and then outputs the serial data groups, although the specification is different depending on the maker. Then, the SP converter detects the head of the data groups by detecting the particular pattern, then joins together the i-th upper bit and the i-th lower bit, and then outputs the resultant parallel data.

However, when this particular pattern is varied by a noise, or the like, such a problem existed that the lower bit side is detected as the head and thus the upper bit and the lower bit of the parallel data go out of synchronization after the transmission.

Here, explanation will be given with reference to FIGS. 6A to 6C hereunder. FIGS. 6A to 6C are views showing schematically the data transmission by using the serial data communication unit in the related art. In FIGS. 6A to 6C, parallel data and a clock signal are input into a PS converter 1. An SP converter 2 reconverts the serial data from the PS converter 1 to the parallel data, and then outputs the parallel data.

FIG. 6A shows a state that the parallel data are input into the PS converter 1, FIG. 6B shows a state that the serial data are now transmitted, and FIG. 6C shows a state that the parallel data reconverted by the SP converter 2 are now output.

In case the parallel data (see FIG. 6A) are converted into the serial data by the PS converter 1 and this converted serial data are affected by the noise (see FIG. 6B), a lack of synchronism is caused between the upper bit and the lower bit, and the parallel data after the transmission are combined like (1-st lower bit, 2-nd upper bit), (2-nd lower bit, 3-rd upper bit), and so on. As a result, the resultant data are totally meaningless as the data (see FIG. 6C).

### SUMMARY

Exemplary embodiments of the present invention provide a serial data communication unit for detecting a lack of synchronism caused during a data transmission of the serial data without fail and a measuring device using the same.

The present invention according to a first aspect provides a serial data communication unit for converting binary-level parallel data into serial data and making a data transmission, and then reconverting the serial data that are transmitted into the parallel data to output the parallel data, which includes a parallel-serial converter for separating n-bit parallel data containing decision data into plural groups, and converting the parallel data into serial data every group to output the serial data; a serial-parallel converter for reconverting the serial data fed from the parallel-serial converter every group into the n-bit parallel data to output the parallel data; and a deciding circuit into which data located in bit positions corresponding to the decision data out of the parallel data from the serial-parallel converter is input.

In the present invention according to a second aspect, in the serial data communication unit according to the first aspect, the deciding circuit makes a decision based on a signal level of the decision data.

In the present invention according to a third aspect, in the serial data communication unit according to the first aspect, the deciding circuit decides whether or not the decision data contained in a first group coincides with the decision data contained in a second group.

In the present invention according to a fourth aspect, in the serial data communication unit according to the first aspect, the deciding circuit makes a decision based on a pattern of the decision data in plural times.

In the present invention according to a fifth aspect, the serial data communication unit according to the first aspect further comprises a decision bit outputting circuit for outputting the decision data to the parallel-serial converter.

The present invention according to a sixth aspect provides a measuring device for taking a measurement by converting a measured signal into a digital signal, which includes an AD converter for converting the measured signal into the digital signal, and outputting m-bit (n>m) parallel data; and the serial data communication unit set forth in any one of the first to five aspects, into which the parallel data from the AD converter are input.

According to the present invention, following advantages can be achieved.

According to the first to fifth aspects, the decision data is contained in the parallel data prior to the transmission, and the deciding circuit employs this decision data out of the parallel data after the transmission. As a result, even when a lack of synchronism of the parallel data is caused, it is feasible to detect such lack of synchronism without fail.

According to the sixth aspect, the measurement can be made by using the parallel data being synchronized, and thus reliability, accuracy, and the like of the data processing can be improved as the measuring device.

### BRIEF DESCRIPTION OF THE DRAWINGS

FIG. 1 is a configurative view showing a first embodiment of the present invention.

FIGS. 2A to 2C are views showing a state of parallel data in a measuring device shown in FIG. 1.

FIG. 3 is a configurative view showing a second embodiment of the present invention.

FIGS. 4A and 4B are views showing a state of parallel data in a measuring device shown in FIG. 3.

FIGS. 5A and 5B are views showing another state of parallel data in the measuring device shown in FIG. 1.

FIGS. 6A to 6C are views showing states of parallel data before and after the transmission and serial data during the transmission.

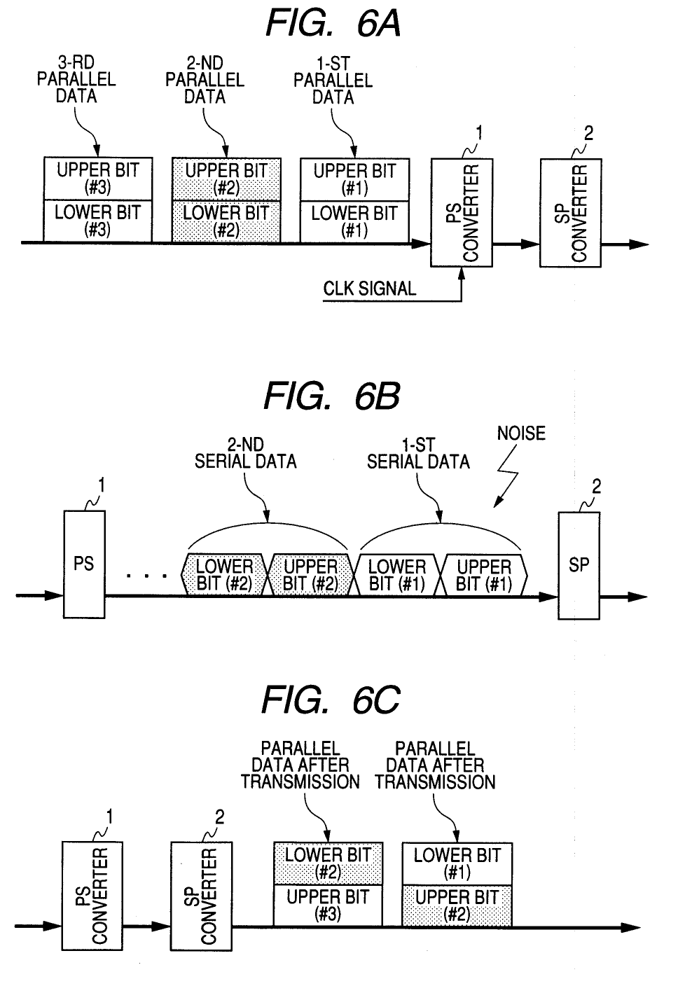

### DETAILED DESCRIPTION

Embodiments of the present invention will be explained with reference to the drawings hereinafter.

### First Embodiment

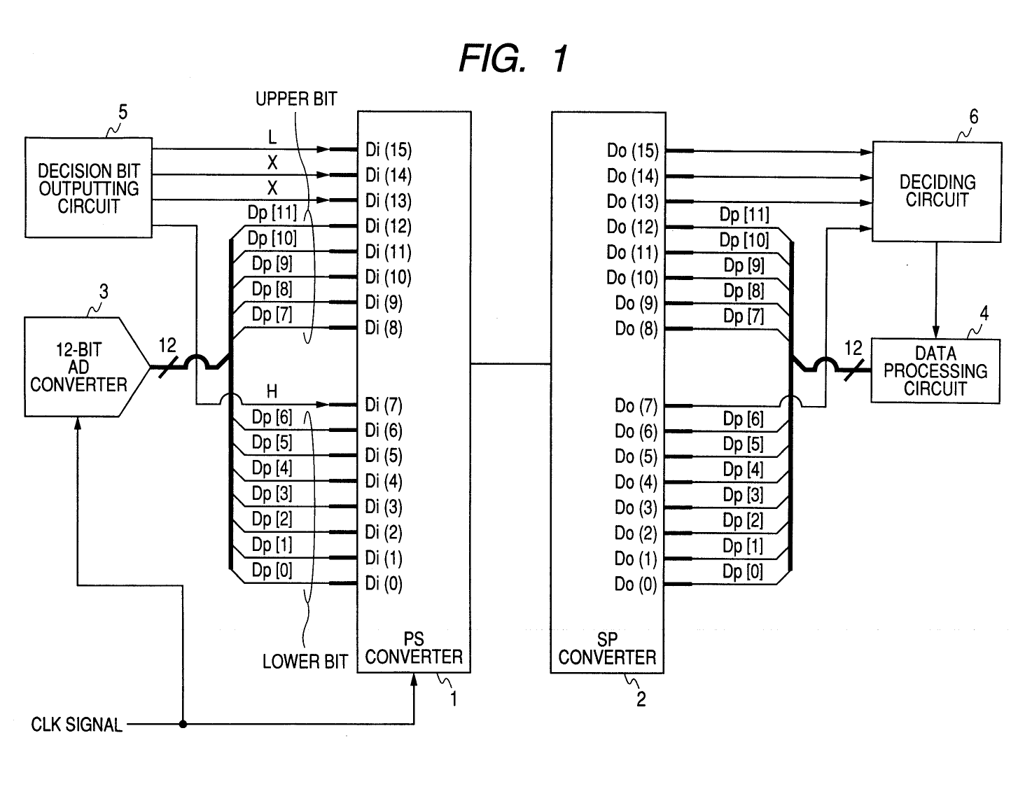

FIG. 1 is a configurative view showing a first embodiment (a measuring device) of the present invention.

In FIG. 1, a configurative example in which a serial data communication unit is employed to transmit digital data (parallel data) from an AD converter to a data processing circuit at the later stage is shown.

A clock signal and the parallel data are input into the PS converter 1. The PS converter 1 has data input terminals (Di(0) to Di(15)) for 16 bits. Then, the PS converter 1 applies the 8b/10b conversion to the parallel data being input into the data input terminals at a binary level every group that consists of 8 bits (a group of input terminals (Di(0) to Di(7) and a group of input terminals (Di(8) to Di(15)), and outputs the serial data on which the clock signal to be supplied is superposed.

The SP converter 2 has 16 output terminals Do(0) to Do(15). The SP converter 2 receives the serial data from the PS converter 1, then converts this serial data into the parallel data, and then outputs the resultant data.

In this case, the communication between the PS converter 1 and the SP converter 2 may be held via either of radio and cable. In the case of cable, any signal such as an electric signal via a metal wire, an optical signal via an optical fiber, and the like may be employed.

Also, the input terminals Di(0) to Di(15) of the PS converter 1 correspond to the output terminals Do(0) to Do(15) of the SP converter 2 respectively. When a lack of synchronism, or the like is not caused during the transmission and the serial data are transmitted normally, the data being input into the input terminal Di(0) is output from the output terminal Do(0), the data being input into the input terminal Di(1) is output from the output terminal Do(1), and so on. Remaining correspondences between remaining terminals are given similarly. Thus, respective terminal numbers (bit positions) correspond to each other.

A measured signal and the clock signal are input into an AD converter 3, and the AD converter 3 outputs digital data repeatedly at a period given based on the clock signal. Also, a resolution of the AD converter 3 is given by 12-bit parallel data Dp[0] to Dp[11], and Dp[11] is the most significant bit. Also, the parallel data Dp[0] to Dp[6] (the lower bit side) of the AD converter 3 are input into the input terminals (Di(0) to Di(6)) of the PS converter 1 respectively, and the parallel data Dp[7] to Dp[11] (the upper bit side) of the AD converter 3 are input into the input terminals (Di(8) to Di(12)) of the PS converter 1 respectively.

A data processing circuit 4 receives the parallel data from the SP converter 2 (the data from the AD converter 3), and executes a predetermined data processing (e.g., an averaging process of the parallel data being transmitted plural times).

A decision bit outputting circuit 5 outputs the decision data at a low level (referred to as an “L level” hereinafter) or a high level (referred to as a “H level” hereinafter) to the terminals (in FIG. 1, the input terminals Di(7), Di(13) to Di(15)), into which the parallel data fed from the AD converter 3 are not input, out of the input terminals Di(0) to Di(15) of the PS converter 1.

A deciding circuit 6 receives the parallel data in the bit positions of the SP converter 2 corresponding to the bit positions of the decision bits of the PS converter 1 (in FIG. 1, the output terminals Do(7), Do(13) to Do(15)). Then, the deciding circuit 6 decides whether or not a lack of synchronism is caused in the data transmission, and outputs the decision result to the data processing circuit 4. In other words, two bits out of four bits of the PS converter 1 and the SP converter 2, which are not used in the data transmission of the AD converter 3 with a 12-bit resolution, are assigned as the decision bits that are handled as the fixed data.

An operation of such device will be explained hereunder.

The AD converter 3 converts the measured signal into the digital signal, and outputs the 12-bit parallel data to the PS converter 1. In this case, the AD converter 3 executes the sampling at a sampling frequency based on the clock signal, and outputs the parallel data in plural times.

Meanwhile, the decision bit outputting circuit 5 outputs the L-level data to the input terminal Di(15), outputs the H-level data to the input terminal Di(7), and outputs the L-level or H-level data to the input terminals Di(14), Di(13).

Then, the PS converter 1 stores the parallel data from the AD converter 3 and the outputting circuit 5 in a buffer (not shown) of the PS converter 1. Then, the PS converter 1 reads the 8-bit parallel date at the input terminals Di(15) to Di(8) (the upper bit side) from the buffer, and then makes the 8b/10b conversion to give a redundancy to the parallel data by 2 bits (in this case, executes the coding to give a particular pattern indicating the head of the serial data group). Then, the PS converter 1 converts the parallel data into the serial data groups while superposing the clock signal, and then outputs the groups to the SP converter 2.

Also, the PS converter 1 reads the 8-bit parallel date at the input terminals Di(7) to Di(0) (the lower bit side) from the buffer, and then makes the 8b/10b conversion to give a redundancy to the parallel data by 2 bits. Then, the PS converter 1 converts the parallel data into the serial data groups by superposing the clock signal, and then outputs the groups to the SP converter 2.

Also, the PS converter 1 converts the upper bit and the lower bit into the serial data respectively every time when the parallel data are input from the AD converter 3, and then outputs the resultant data to the SP converter 2.

Consequently, the PS converter 1 transmits the parallel data fed from the AD converter 3 to the SP converter 2 sequentially in order of the serial data group containing the 1-st upper bit→the serial data group containing the 1-st lower bit→the serial data group containing the 2-nd upper bit→the serial data group containing the 2-nd lower bit→the serial data group containing the 3-rd upper bit, . . . , and so on.

Then, the SP converter 2 stores the serial data groups from the PS converter 1 in a buffer (not shown) of the SP converter 2. Then, the SP converter 2 reproduces the clock signal from the received serial data, then converts the serial data into the parallel data at a timing based on the clock signal, and then removes the redundant bits from the 10-bit parallel data to reproduce the 8-bit parallel data.

Then, the SP converter 2 identifies the serial data group serving as the head data (the upper bit side), then outputs the serial data group being identified as the head data from the output terminals Do(8) to Do(15) as the upper bit side, and then outputs the serial data group being input next from the output terminals Do(0) to Do(7) as the lower bit side respectively. Of course, the upper bit side and the lower bit side are synchronized, and thus the parallel data are output from the terminals Do(0) to Do(15).

Then, the data processing circuit 4 executes a data processing (e.g., an averaging process) Also, the deciding circuit 6 checks the signal level of the data in the bit position (the output terminals Do(15), Do(7)) corresponding to the decision data of the parallel data fed from the SP converter 2. When the signal level of the output terminal Do(15) is the L level and the signal level of the output terminal Do(7) is the H level, the deciding circuit 6 decides that the data transmission was made normally. In contrast, when the signal level of the output terminal Do(15) is the H level and the signal level of the output terminal Do(7) is the L level, the deciding circuit 6 decides that the data transmission failed. Then, the deciding circuit 6 outputs the decision result to the data processing circuit 4 to interrupt the process of the parallel data whose transmission failed. Also, as occasion demands, the deciding circuit 6 demands of the PS converter 1 the retransmission of the parallel data whose transmission failed.

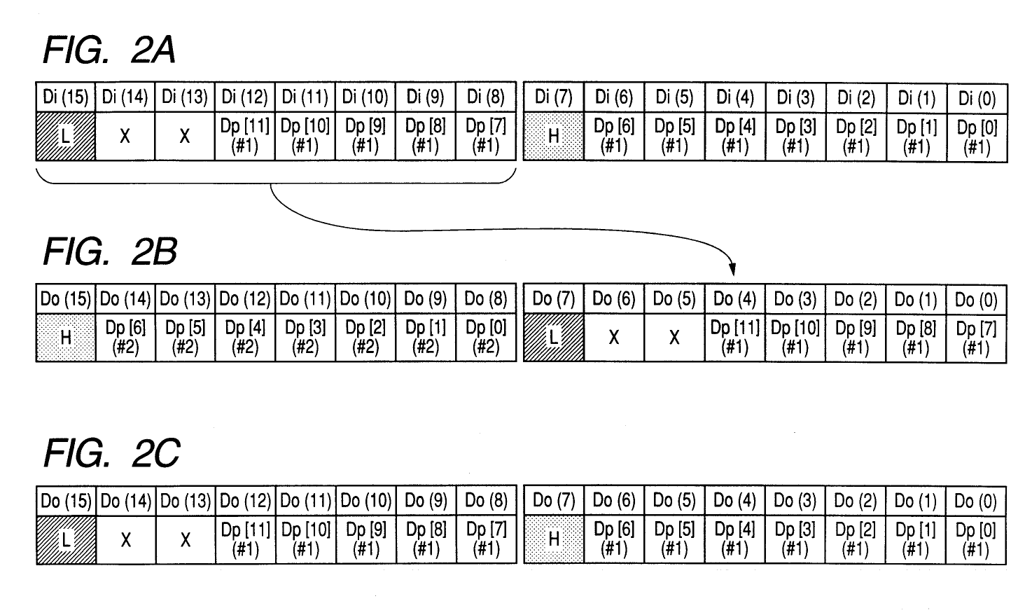

Here, explanation will be made concretely with reference to FIGS. 2A to 2C hereunder. FIGS. 2A to 2C are views showing states before and after the parallel data in the measuring device shown in FIG. 1 are transmitted. FIG. 2A shows the parallel data that are input into respective input terminals Di(0) to Di(15) of the PS converter 1, FIG. 2B shows the parallel data that are output from respective output terminals Do(0) to Do(15) of the SP converter 2 when the transmission failed, and FIG. 2C shows the parallel data that are output from respective output terminals Do(0) to Do(15) of the SP converter 2 when the transmission succeeded.

As shown in FIG. 2A, the L-level data is always input into the input terminal Di(15) that belongs to the upper bit side, and the H-level data is always input into the input terminal Di(7) that belongs to the lower bit side.

Therefore, when the transmission succeeded, the data from the output terminal Do(15) is at the L level and the data from the output terminal Do(7) is at the H level, as shown in FIG. 2C. In contrast, when the transmission failed, the signal levels of the data from the output terminals Do(15), Do(7) are inverted, as shown in FIG. 2B. As a result, the deciding circuit 6 can detect whether or not a lack of synchronism was caused, by deciding the signal levels at the predetermined output terminals Do(15), Do(7).

In this manner, the decision bit outputting circuit 5 assigns the fixed data to the bits that are not used in the data transmission of the AD converter 3. Concretely, the decision bit outputting circuit 5 outputs the L-level data to the input terminal Di(15) of the PS converter 1 that belongs to the upper bit side of the AD converter 3, and outputs the H-level data to the input terminal Di(7) of the PS converter 1 that belongs to the lower bit side of the AD converter 3. Then, the deciding circuit 6 decides the signal levels of the output terminal Do(15) of the SP converter 2 corresponding to the input terminal Di(15) and the output terminal Do(7) of the SP converter 2 corresponding to the input terminal Di(7). As a result, even when a lack of synchronism is caused between the data on the upper bit side and the data on the lower bit side by the noise during the transmission, the deciding circuit 6 can detect a lack of synchronism without fail based on the signal levels of the output terminals Do(7), Do(15).

Also, the data processing circuit 4 can process only the parallel data that are synchronized. Thus, reliability, accuracy, and the like of the data processing can be improved as the measuring device.

### Second Embodiment

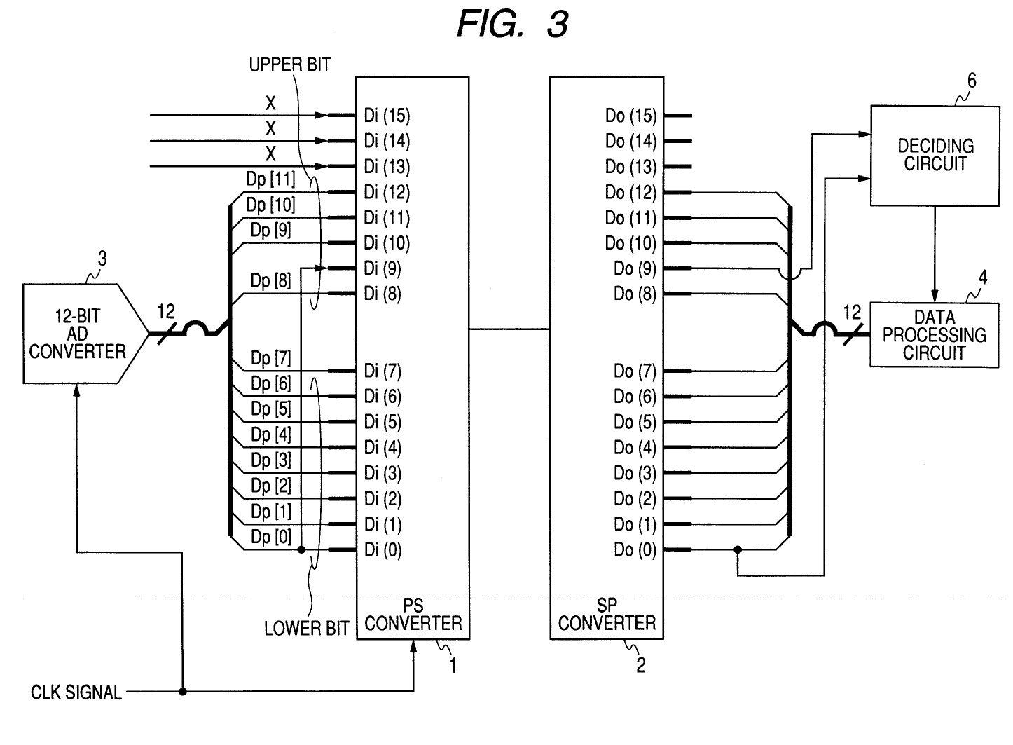

FIG. 3 is a configurative view showing a second embodiment of the present invention. Here, the same reference symbols are affixed to the same constituent elements as those in FIG. 1, and therefore their explanation will be omitted herein. In FIG. 3, the decision bit outputting circuit 5 is removed.

The data Dp[0] to Dp[7] (the lower bit side) from the AD converter 3 are input into the input terminals Di(0) to Di(7) of the PS converter 1 respectively. Also, the data Dp[8] to Dp[11] (the upper bit side) from the AD converter 3 are input into the input terminals Di(8), Di(10) to Di(12) of the PS converter 1 respectively.

Also, the same data as the data of the input terminal Di(0) (the data of the least significant bit of the AD converter 3) is input into the input terminal Di(9) of the PS converter 1. Also, the L-level or H-level data is input into the input terminals Di(13) to Di(15) respectively.

The data fed from the output terminals Do(0) to Do(8), Do(10) to Do(12) of the SP converter 2 are input into the data processing circuit 4.

The data fed from the output terminals Do(0), Do(9) of the SP converter 2 (the data corresponding to the least significant bit of the AD converter 3) are input into the deciding circuit 6.

An operation of such device will be explained hereunder.

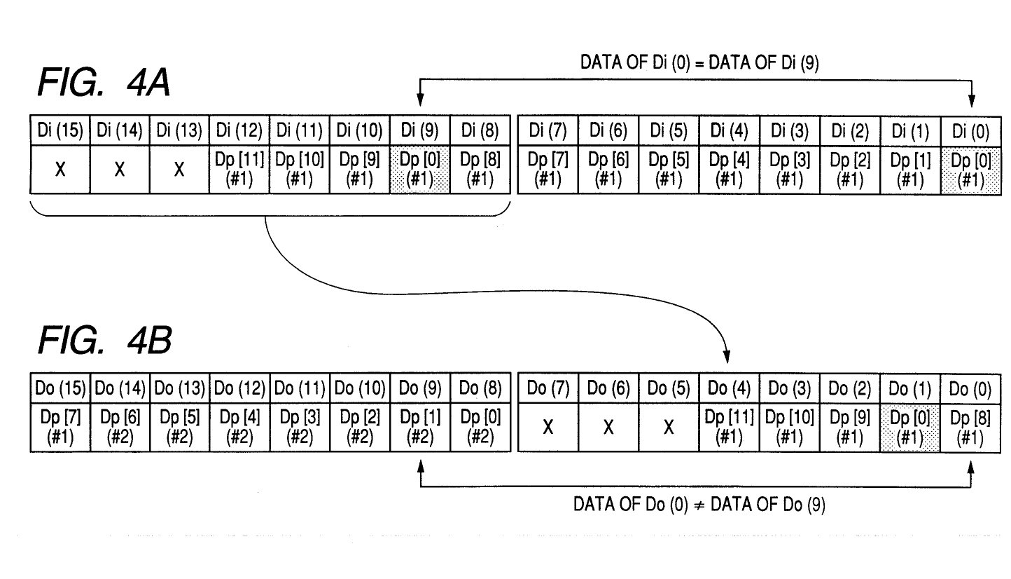

Here, explanation will be made concretely with reference to FIGS. 4A and 4B hereunder. FIGS. 4A and 4B are views showing states before and after the parallel data in the measuring device shown in FIG. 3 are transmitted. FIG. 4A shows the parallel data that are input into the input terminals Di(0) to Di(15) of the PS converter 1, and FIG. 4B shows the parallel data that are output from the output terminals Do(0) to Do(15) of the SP converter 2 when the transmission failed.

The data of the least significant bit out of the data from the AD converter 3 is always varied by the noise, or the like. In this event, as shown in FIG. 4A, the same data (the data of the least significant bit of the AD converter 3) is input into the input terminals Di(0), Di(9) respectively.

Then, the deciding circuit 6 decides whether or not the data fed from the output terminals Do(0), Do(9) of the SP converter 2 corresponding to the input terminals Di(0), Di(9) coincide with each other.

More particularly, the data from the output terminals Do(0), Do(9) coincide with each other when the transmission succeeded, while the data from the output terminals Do(0), Do(9) do not coincide with each other when the transmission failed. Then, the deciding circuit 6 detects whether or not a lack of synchronism is caused, by deciding the signal levels of the predetermined output terminals Do(0), Do(9). Since other operations are similar to those of the measuring device shown in FIG. 1, their explanation will be omitted herein.

In this manner, the deciding circuit 6 decides whether or not the data coincide mutually, by using the signal levels of the output terminals Do(0), Do(9) of the SP converter 2, from which the data corresponding to the least significant bit is output. Therefore, even when a lack of synchronism is caused between the data of the upper bit side and the data of the lower bit side during the transmission by the noise, the deciding circuit 6 can detect a lack of synchronism without fail.

Here, the present invention is not limited to this mode. Various modes shown as follows may be employed.

1) In the device shown in FIG. 1 and FIG. 3, any bit combination may be employed as the upper bit side and the lower bit side of the AD converter 3.

2) In the device shown in FIG. 1 and FIG. 3, the system using the 8b/10b conversion is illustrated as an example of the parallel-serial conversion 1 and the serial-parallel conversion 2. But any converting system may be employed.

3) In the device shown in FIG. 1 and FIG. 3, such a configuration is illustrated that the AD converter 3 outputs the parallel data of 12 bits. But the parallel data of any bit may be output. Also, such a configuration is illustrated to explain the PS converter 1 and the SP converter 2 that the 16-bit parallel data are converted into the serial data every group of 8 bits. But any bit may be set to the input/output terminals, and also any bit number may be employed as a group. In this case, when the AD converter 3 outputs the parallel data of m bits, the bit number n of the input/output terminals of the PS converter 1 and the SP converter 2 should be set to satisfy n>m.

4) In the device shown in FIG. 1, such a configuration is illustrated that 2 bits out of 4 bits that are not used for the data transmission of the AD converter 3 are assigned to the fixed data. But 3 bits out of 4 bits or all 4 bits may be assigned to the fixed data for the purpose of decision.

5) In the device shown in FIG. 1, such a configuration is illustrated that the decision bit outputting circuit 5 maintains the signal levels of the decision bits (the input terminals Di(7), Di(15) of the PS converter 1) constant. In this case, when the signal level is changed in synchronism with the data output of the AD converter 3 (i.e., in synchronism with the clock signal), the deciding circuit 6 may detect a lack of synchronism based on the pattern of the signal level of the data from the output terminals Do(7), Do[15].

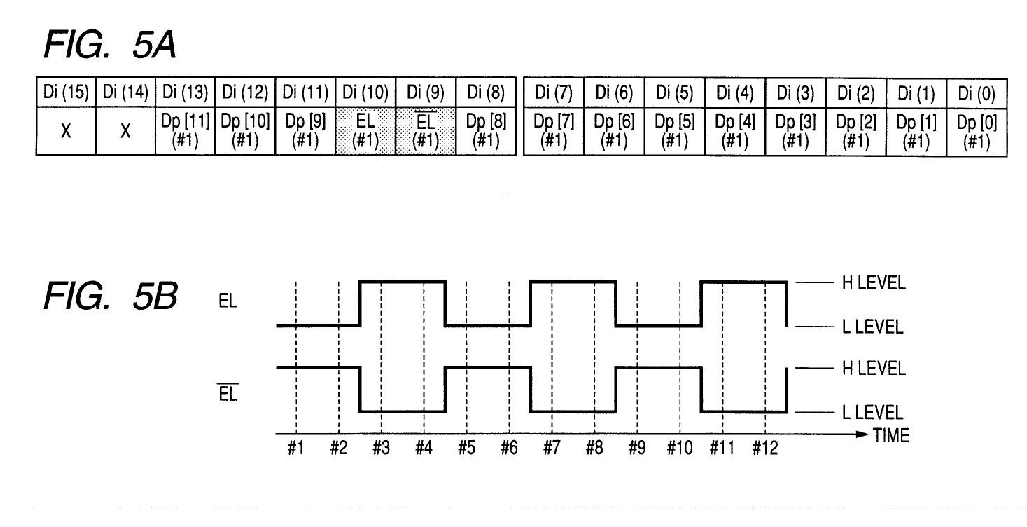

Here, explanation will be made concretely with reference to FIGS. 5A and 5B hereunder. FIGS. 5A and 5B are views showing another state before the parallel data in the measuring device shown in FIG. 1 are transmitted. FIG. 5A shows the parallel data that are input into the input terminals Di(0) to Di(15) of the PS converter 1, and FIG. 5B shows patterns of the decision data from the outputting circuit 5.

In FIG. 5A, by way of example, the data Dp[0] to Dp[7] (the lower bit side) from the AD converter 3 are input into the input terminals Di(0) to Di(7) of the PS converter 1 respectively, while the data Dp[8] to Dp[11] (the upper bit side) from the AD converter 3 are input into the input terminals Di(8), Di(11) to Di(12) of the PS converter 1 respectively. Also, the outputting circuit 5 outputs the decision data to the input terminals Di(9), Di(10).

In such device, the deciding circuit 6 checks the pattern of the data of the output terminals Do(9), Do(10) of the SP converter 2 corresponding to the input terminals Di(9), Di(10), and then decides whether or not such pattern coincides with the reference pattern (see FIG. 5B). This reference pattern is set in advance in the outputting circuit 5 and the deciding circuit 6.

In other words, when the transmission succeeded, the patterns of the data from the output terminals Do(9), Do(10) coincide with the pattern of the outputting circuit 5, as shown in FIG. 5B. Therefore, the deciding circuit 6 detects whether or not a lack of synchronism is caused, by deciding the bit pattern. Since remaining operations are similar to those of the device shown in FIG. 1, their explanation will be omitted herein.

Also, in FIG. 5A, the decision of the pattern is made by using 2 bits. Of course, the decision of the pattern may be made by using 1 bit, 3 bits, or 4 bits.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A serial data communication unit for converting binary-level parallel data into serial data and making a data transmission, and then reconverting the serial data that are transmitted into the parallel data to output to parallel data, comprising:
a parallel-serial converter for separating n-bit parallel data containing decision data into plural groups, and converting the parallel data into serial data every group to output the serial data;
a serial-parallel converter for reconverting the serial data fed from the parallel-serial converter every group into the n-bit parallel data to output the parallel data; and
a deciding circuit into which data located in bit positions corresponding to the decision data out of the parallel data from the serial-parallel converter is input.

2. A serial data communication unit according to claim 1, wherein the deciding circuit makes a decision based on a signal level of the decision data.

3. A serial data communication unit according to claim 1, wherein the deciding circuit decides whether or not the decision data contained in a first group coincides with the decision data contained in a second group.

4. A serial data communication unit according to claim 1, wherein the deciding circuit makes a decision based on a pattern of the decision data in plural times.

5. A serial data communication unit according to claim 1, further comprising:
a decision bit outputting circuit for outputting the decision data to the parallel-serial converter.

6. A measuring device for taking a measurement by converting a measured signal into a digital signal, comprising:
an AD converter for converting the measured signal into the digital signal, and outputting m-bit (n>m) parallel data; and
the serial data communication unit set forth in claim 1, into which the parallel data from the AD converter are input.

7. A measuring device for taking a measurement by converting a measured signal into a digital signal, comprising:
an AD converter for converting the measured signal into the digital signal, and outputting m-bit (n>m) parallel data; and
the serial data communication unit set forth in claim 2, into which the parallel data from the AD converter are input.

8. A measuring device for taking a measurement by converting a measured signal into a digital signal, comprising:
an AD converter for converting the measured signal into the digital signal, and outputting m-bit (n>m) parallel data; and
the serial data communication unit set forth in claim 3, into which the parallel data from the AD converter are input.

9. A measuring device for taking a measurement by converting a measured signal into a digital signal, comprising:
an AD converter for converting the measured signal into the digital signal, and outputting m-bit (n>m) parallel data; and
the serial data communication unit set forth in claim 4, into which the parallel data from the AD converter are input.

10. A measuring device for taking a measurement by converting a measured signal into a digital signal, comprising:
an AD converter for converting the measured signal into the digital signal, and outputting m-bit (n>m) parallel data; and
the serial data communication unit set forth in claim 5, into which the parallel data from the AD converter are input.
